(19) United States
(12) Patent Application Publication
(10) Pub. No.: US 2020/0006169 A1
(43) Pub. Date: Jan. 2, 2020

(54) MICRO-ELECTRONIC PACKAGE WITH BARRIER STRUCTURE

(71) Applicant: Intel Corporation, Santa Clara, CA (US)

(72) Inventors: William WARREN, Chandler, AZ (US); Taylor GAINES, Chandler, AZ (US); Frederick ATADANA, Chandler, AZ (US); Edvin CETEGEN, Chandler, AZ (US); Vipul MEHTA, Chandler, AZ (US); Hsin-Yu LI, Chandler, AZ (US); Yuying WEI, Chandler, AZ (US); Yang GUO, Chandler, AZ (US); Ren ZHANG, Chandler, AZ (US)

(21) Appl. No.: 16/022,528

(22) Filed: Jun. 28, 2018

(51) Int. Cl. H01L 23/16; H01L 23/31

(52) U.S. Cl. CPC H01L 23/16; H01L 23/3157

(57) ABSTRACT

A structure including a barrier is described. In embodiments, a micro-electronic component may have a first face and a second face, wherein the second face includes interconnect structures and is opposite the first face. A fill material, such as a capillary underfill material (CUF), may fill a gap between the micro-electronic component and the substrate and substantially surround the interconnect structures. In embodiments, a barrier structure may be located on the surface of the substrate and along a perimeter or outside perimeter of the micro-electronic component, wherein a height of the barrier structure exceeds a height of the fill material in at least a portion of an open region of the substrate to confine the fill material to an area bordered by the barrier structure.

### TECHNICAL FIELD

Embodiments of the disclosure relate to semiconductor structures and packaging and, more particularly, to micro-electronic packages with a barrier to facilitate the dispensing of capillary underfill material.

### BACKGROUND

Integrated circuits typically include various active and passive circuit elements that have been integrated into a piece of semiconductor material, often referred to as a die. The die may, in turn, be encapsulated into a package. Device packaging challenges have grown as cost-reduction and continuous space demands related to the integration of electronic packages into compact devices. For example, in flip chip technology, encapsulation may include a process called underfill dispensing, which fills the space between the flip chip and substrate with a polymer epoxy. Such challenges include but are not limited to, for example, void formation in the epoxy and keep out zone (KOZ) violations. A KOZ is the protected area on an electronic package that avoids epoxy contamination on a die surface and nearby components.

### BRIEF DESCRIPTION OF THE DRAWINGS

FIGS. 1A-1C are illustrations of cross-sectional and top views of a structure 100 associated with a formation of a barrier on a substrate, in accordance with various embodiments.

FIG. 2 is an illustration of a cross-sectional and top view of a structure 200 associated with the embodiments of FIGS. 1A-1C, in accordance with various embodiments.

FIG. 3 is an illustration of cross-sectional view of a structure 300 that shows a relationship between one or more elements of FIGS. 1A-1C, in accordance with various embodiments.

FIG. 4 is a flow diagram 400 associated with the embodiments of FIGS. 1-3, in accordance with various embodiments.

FIG. 5 is an illustration of a top view of a device 500 that illustrates an example reduction of a keep out zone (KOZ) on a substrate, in accordance with various embodiments.

FIG. 6 is a top view of a device 600, in accordance with various embodiments.

FIG. 7 is an illustration of a cross-sectional view of a device 700, in accordance with various embodiments.

FIG. 8 is an illustration of a cross-sectional view of a device 800 in accordance with various embodiments.

FIG. 9 a schematic of a computing device 900, in accordance with an embodiment of the present disclosure.

FIG. 10 illustrates an interposer 1000 that includes one or more embodiments of the invention as discussed in connection with FIGS. 1-9.

### DESCRIPTION OF THE EMBODIMENTS

This Specification describes a micro-electronic package with a barrier structure (“barrier”) to facilitate dispense of underfill (also referred to as “encapsulant material” or “fill material”) to substantially confine the underfill to an area bordered by the barrier. In embodiments, a structure may include a micro-electronic component having a first face and a second face, wherein the second or bottom face includes interconnect structures and is opposite the first face. In embodiments, the structure may include underfill material that substantially fills a gap between the micro-electronic component and the substrate and substantially surrounds the interconnect structures. In embodiments, the barrier may be located on the surface of the substrate and along a perimeter or outside perimeter of the micro-electronic component. In embodiments, a height of the barrier may exceed a height of the underfill material in at least a portion of an open region of the substrate to confine the underfill material to an area bordered by the barrier.

In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure; however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper,” “lower,” “above,” and “below” refer to directions in the drawings to which reference is made. Terms such as “front,” “back,” “rear,” and “side” describe the orientation and/or location of portions of the component within a consistent but arbitrary frame of reference that is made clear by reference to the text and the associated drawings describing the component under discussion. Such terminology may include the words specifically mentioned above, derivatives thereof, and words of similar import.

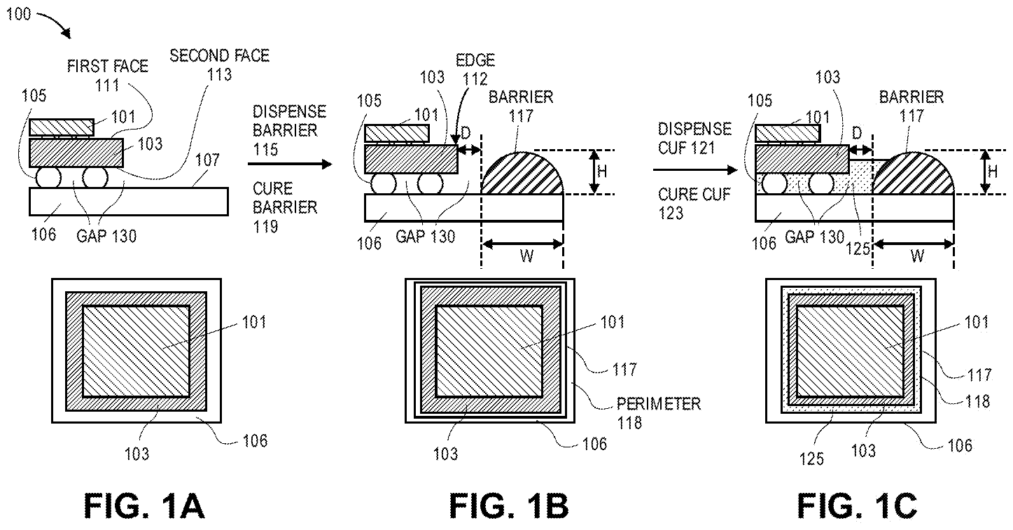

FIGS. 1A-1C include cross-sectional and top views of a structure 100 associated with formation of a barrier structure (“barrier”) on a substrate, in accordance with embodiments. In embodiments, the barrier may serve as a flow barrier to confine an underfill material to an area that may be proximate to, or substantially surrounded by, the barrier, in accordance with various embodiments. Shown in upper and lower portions of FIGS. 1A-1C are respective cross-sectional and top views of structure 100. In embodiments, structure 100 may include a first component that may include a micro-electronic component or device, e.g., a semiconductor die 101 (“die 101”) coupled to a second component that may include another micro-electronic component or device, such as another semiconductor die, or an intervening or interconnection component, such as, e.g., a patch structure 103. Accordingly, in various embodiments, patch structure 103 may provide connections and/or other functions to one or more micro-electronic devices or structures coupled to patch structure 103. In the illustrated embodiment, patch structure 103 may have a first face 111 opposite to a second face 113 (note that for clarity in the FIGS., like elements may not necessarily be labeled across FIGS. 1A-1C). In embodiments, second face 113 may be a bottom face and may include interconnect structures 105, such as, e.g., mid-level interconnect (MLI) structures that may include pads and/or solder balls such as included in a ball-grid array (BGA).

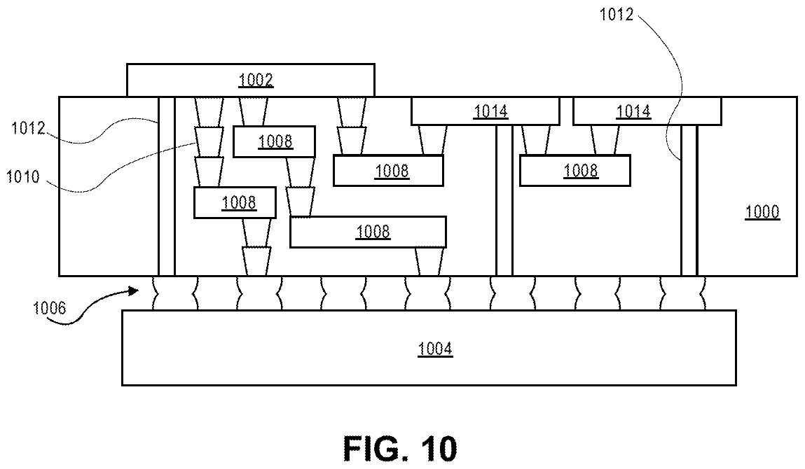

Structure 100 may also include a third component, e.g., a substrate 106, located below patch structure 103, in embodiments. Accordingly, in some embodiments, structure 100 may include a package structure such as, e.g., a patch on interposer (PoINT) structure. In embodiments, substrate 106 may be any suitable substrate having a top surface 107 to which second face 113 of patch structure 103 may be electrically coupled. In an embodiment, for example, substrate 106 may be an intervening substrate such as an interposer (discussed in more detail with respect to FIG. 10). In other embodiments, substrate 106 may be another micro-electronic component such as, but not limited to, a printed circuit board (PCB) or motherboard. In embodiments, at 115, a barrier 117, as shown in FIG. 1B, may be dispensed onto surface 107 of substrate 106. As shown in the top view in FIG. 1B, barrier 117 may be dispensed along a perimeter 118 outside of an edge 112 of patch structure 103, in embodiments.

In embodiments, barrier 117 may be formed from a different material than that of substrate 106. In some embodiments, barrier 117 may be formed from a similar or same material than that of substrate 106. In embodiments, barrier 117 may include any suitable material that may provide a physical or chemical barrier to substantially confine an underfill or fill material 125 to an area on substrate 106 substantially surrounded by, or proximate to, barrier 117. For example, in various embodiments, barrier 117 may be formed of but is not limited to epoxy materials such as one or more of amines, anhydrides, urethanes, cyanos, cationic epoxies. In some embodiments, barrier 117 may include an acrylate or other material. Accordingly, barrier 117 may be dispensed in fluid form along perimeter 118 and may be dispensed using an automated/computerized dispense platform. In embodiments of the disclosure described herein, such as with reference to FIGS. 1-8, barrier material can be dispensed in any suitable manner of dispensing a physical or chemical barrier.

In the embodiment, if barrier 117 is made of a material such as an epoxy or other material that requires curing, barrier 117 may be cured (e.g., see 119). In embodiments, barrier 117 may include a height H, width W, and be a distance D from an edge 112 of patch structure 103. Accordingly, in embodiments, an open region of substrate 106 may include an open region having a distance D between barrier 117 and edge 112 of patch structure 103. In embodiments, fill material 125 such as a capillary underfill (CUF) material may be dispensed (e.g., at 121). In embodiments, a process used to dispense fill material 125 may include any suitable manner of dispensing a CUF encapsulant material to provide support and protection to interconnect structures 105.

Accordingly, in embodiments, fill material 125 may be dispensed in an open region of substrate 106 between an inside surface of barrier 117 and edge 112 of patch structure 103. In embodiments, fill material 125 may fill a gap 130 between patch structure 103 and substrate 106 and substantially surround interconnect structures 105. In embodiments, a height H of barrier 117 may exceed a height of fill material 125 in at least a portion of an open region of substrate 106 to confine fill material 125 to an area bordered by barrier 117. In embodiments, the fill material or CUF may be cured at 123.

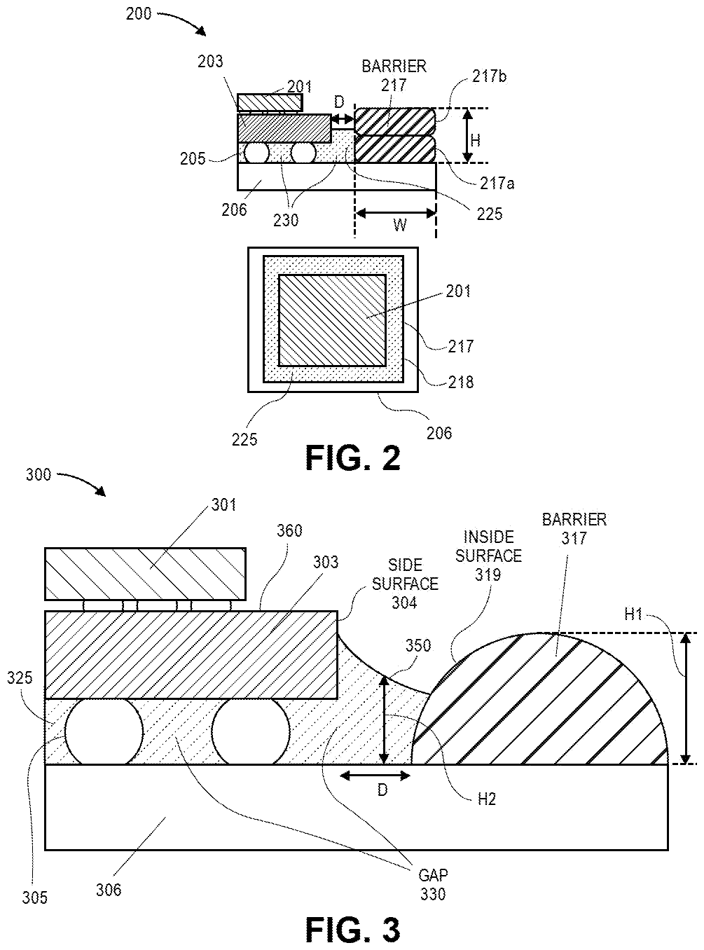

FIG. 2 is an illustration of a cross-sectional and top view of a structure 200 associated with the embodiments of FIGS. 1A-1C, in accordance with various embodiments. In embodiments, structure 200 may be associated with adjusting a height of a barrier 217. In embodiments, an upper portion of FIG. 2 illustrates a cross-sectional view of structure 200. In embodiments, structure 200 may include a first component such as a micro-electronic component, e.g., die 201, a second component such as another micro-electronic component, or, e.g., a patch structure 203. In embodiments, patch structure 203 may include interconnect structures 205 a face or an underside of patch structure 203. In embodiments, structure 200 may also include a third component, e.g., a substrate 206. In embodiments, barrier 217 may be formed of, e.g., two barriers 217a and 217b stacked substantially upon each other. In embodiments, after a first epoxy bead may be dispensed along a border or perimeter 218 located on substrate 206, a second epoxy bead may be dispensed over a surface of the first epoxy bead to result in a height (H) of barrier 217. Note that although two barriers are shown as stacked upon each other in FIG. 2, in various embodiments, any number of barriers may be dispensed along the perimeter and stacked/located upon each other to achieve any suitable height to confine fill material 225 to an area on substrate 206 substantially surrounded by, or proximate to, barrier 217. In embodiments, fill material 225 may substantially fill a gap 230 to protect interconnect structures 205.

FIG. 3 is an illustration of a cross-sectional view of a structure 300 that shows a relationship between one or more elements of FIGS. 1A-1C and FIG. 2, in accordance with various embodiments. In embodiments, structure 300 may include a first component such as a micro-electronic component, such as a die 301, a second component such as another die, or micro-electronic component, e.g., a patch structure 303. In embodiments, structure 300 may also include a third component, e.g., such as a substrate 306. In embodiments, a capillary underfill material (CUF) such as a fill material 325 may fill a gap 330 between second component 303 and substrate 306. In embodiments, fill material 325 may substantially surround interconnect structures 305. Fill material 325 may form a fillet 350 between a side surface 304 of patch structure 303 and an inside surface 319 of barrier 317, in embodiments. Note that, in embodiments, a first face of patch structure 303 may include a top face 360 and may remain above a level of fill material 325. In embodiments, top face 360 of patch structure 303 may not have any contact with fill material 325. As shown in FIG. 3, in embodiments, a height H1 of barrier 317 may exceed a height of fill material 325 (e.g., H2) in at least a portion of an open region (as indicated at D) of substrate 306 to confine fill material 325 to an area bordered by barrier structure or barrier 317. In embodiments, height H1 of barrier 317 may be adjusted to any suitable height according to device parameters and thus may vary from microns to centimeters.

In embodiments, usage of barrier(s) similar to barriers 117, 217, and 317, in conjunction with dispensation of fill material 125, may allow an increase in shot weight and thus reduce voiding. In embodiments, barrier 117 may allow an increase in capillary pressure at a tongue side and an increase in flow speed of fill material 125 as well as reduce or eliminate tongue epoxy starvation. In embodiments, in addition to void reduction, processing time per structure or unit may be reduced due to an increased hydrostatic and capillary pressure allowed by usage of barrier 117 in conjunction with dispensation of fill material 125.

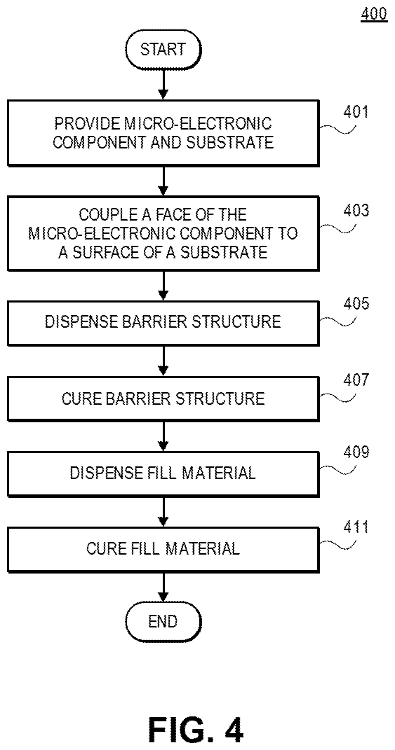

FIG. 4 is a flow diagram illustrating a process 400 associated with the embodiments of FIGS. 1-3. In embodiments, process 400 may include providing a micro-electronic component and a substrate at a block 401. In some embodiments, providing the micro-electronic component and substrate may include forming micro-electronic devices using various suitable semiconductor and packaging processes. At a next block 403, in embodiments, process 400 may include coupling a face of the micro-electronic component, e.g., bottom or second face 113 of FIGS. 1A-1C, to e.g., surface 107 of substrate 106. Next at a block 405, according to embodiments, a barrier structure or barrier, e.g., barrier 117 of FIGS. 1A-1C, may be dispensed along a perimeter or outside perimeter of the micro-electronic component along the substrate.

In embodiments, the barrier may include an epoxy or other suitable physical or chemical barrier that may provide a barrier structure to confine or substantially confine a fill material to an area on the substrate. In embodiments, as noted above, the barrier may include an epoxy material such as one or more of amines, anhydrides, urethanes, cyanos, cationic epoxies. In embodiments, dispensing the barrier comprises dispensing an epoxy material that includes a silica filler. In some embodiments, the barrier may include an acrylate or other material. In embodiments, the barrier, if made of an epoxy or other material that may require curing, may be cured at a block 407. Furthermore, in embodiments, dispensing the barrier may include dispensing the barrier along a substantially level surface of the surface of the substrate. Accordingly, in various embodiments, although the barrier may be dispensed in a trench, process 400 does not require relying on a trench to prevent flow of fill material 125. Next process 400 may include at block 409, in embodiments, dispensing an encapsulant material or fill material, e.g., CUF, to fill a gap, e.g., gaps 130, 230, or 330 of FIGS. 1A-C, 2, and 3, to substantially surround interconnect structures such as may be included between the micro-electronic component and a surface of the substrate. Finally, at a block 411, the fill material may be cured.

In alternate embodiments, a barrier may be formed from a similar or same material than that of substrate 106. Accordingly, in some embodiments, the barrier may be formed by similar or same methods used to form substrate 106 (not shown in connection with process 400). In some embodiments, such a method may include using a solder resist, or adding, depositing, or etching material to form the barrier.

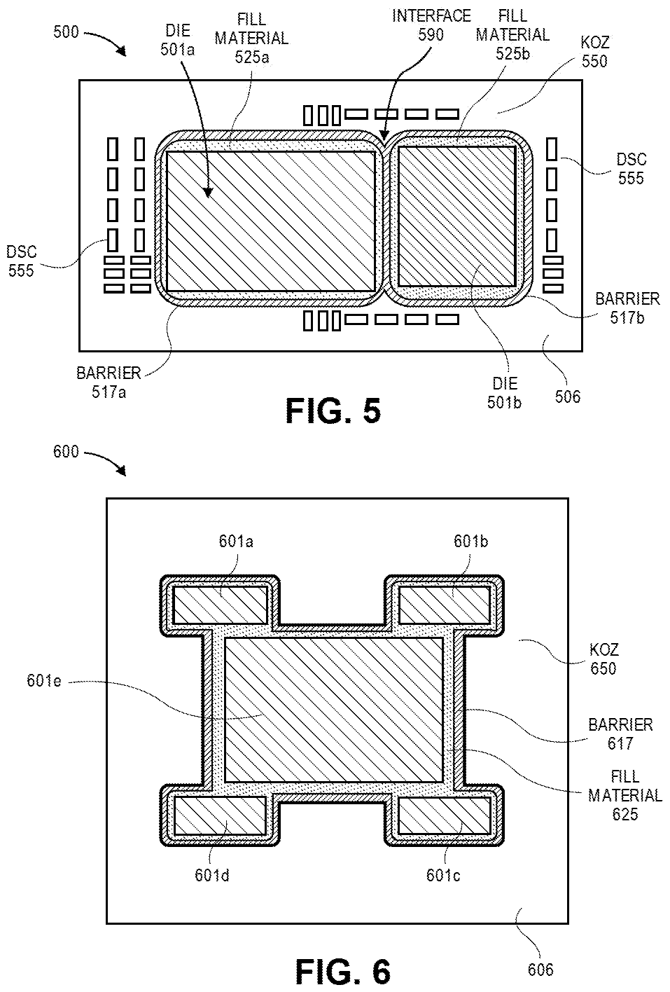

In the embodiments of FIGS. 1-4, the first component, second component, and third component have been depicted as a respective die, patch structure, and interposer, for example purposes only. Note that in various embodiments, the components may be interchangeable and/or may include any other suitable micro-electronic components that may benefit from including a barrier similar to embodiments as described in the present disclosure. Furthermore, in embodiments (and as seen in additional embodiments associated with FIGS. 5-8), a structure may include a fewer or greater number of micro-electronic components or devices than as described in connection with FIGS. 1-4. Accordingly, embodiments may be associated with, but not limited to, mid-level interconnect (MLI), system-level interconnect (SLI), board-level underfill (BLUF) structures or semiconductor packages, or devices, where a barrier as described above can facilitate dispensing of underfill or fill material.

FIG. 5 is a top view of a device 500 that illustrates a reduction of a keep out zone (KOZ) 550 on a substrate 506, in accordance with embodiments. In embodiments, barriers 517a and 517b may serve as flow barriers to prevent spreading of fill material(s) 525a and 525b. In various embodiments, as compared to other methods associated with dispensing of CUF or fill materials, barriers 517a and 517b may allow dispensation of a relatively large amount of fill material, while resulting in fewer and/or significantly reduced keep out zone (KOZ) violations. Accordingly, in various embodiments, an additional substrate area reserved or required for excess fill material may be reduced, thus improving usage of area on substrate 506.

In embodiments, device 500 may include, e.g., an intervening structure such as an interposer or other device including substrate 506 such as, for example, a printed circuit board (PCB) or other board. In embodiments, device 500 may include a first structure including a first integrated circuit (IC) or semiconductor die 501a (“die 501a”) and a second structure including a second IC or semiconductor die 501b (“die 501b”). In embodiments, device 500 may include a plurality of components such as die-side components (DSC) 555 coupled to substrate 506. In embodiments, barrier structures, e.g., barrier 517a and barrier 517b, may be located outside a perimeter of die 501a and 501b, substantially along a perimeter of KOZ 550 on a surface of substrate 506.

In the embodiment shown, barrier 517a and barrier 517b may abut or substantially abut each other and may include an interface 590 that may allow first die 501a and second die 501b to be located with a reduced KOZ 550 between first die 501a and second die 501b. In other embodiments (not shown), barrier 517a and barrier 517b may not necessarily abut each other, but may provide a smaller KOZ 550 between a first die 501a and a second die 501b as compared to other CUF processes. In embodiments, respective fill materials 525a and 525b may be confined or substantially confined to an area surrounded by or proximate to a barrier 517a and barrier 517b corresponding to respective die 501a and 501b. In some embodiments, a first fill material 525a underneath first die 501a and a second fill material 525b underneath second die 501b may include a same fill material. In other embodiments, first fill material 525a and second fill material 525b may include different fill materials. In embodiments, reduction of an area of KOZ 550 between first die 501a and second die 501b may improve an electrical performance of device 500.

FIG. 6 is a top view of another device 600 that illustrates a reduction of a keep out zone (KOZ) 650 on a substrate 606, in accordance with embodiments. In embodiments, device 600 may be, e.g., an intervening structure such as an interposer or other device such as, but not limited to, a printed circuit board (PCB) or other board that may include a substrate on which micro-electronic components may be coupled. In embodiments, device 600 may include a plurality of micro-electronic components that may include a plurality of integrated circuit dies, e.g., plurality of dies 601a-601d. In embodiments, plurality of dies 601a-601d may be memory dies that may flank another micro-electronic component, e.g., another die, such as a processor die 601e. In embodiments, a barrier 617 may substantially surround a fill material 625 that fills a gap between a surface of substrate 606 and plurality of memory dies 601a-601d and processor die 601e.

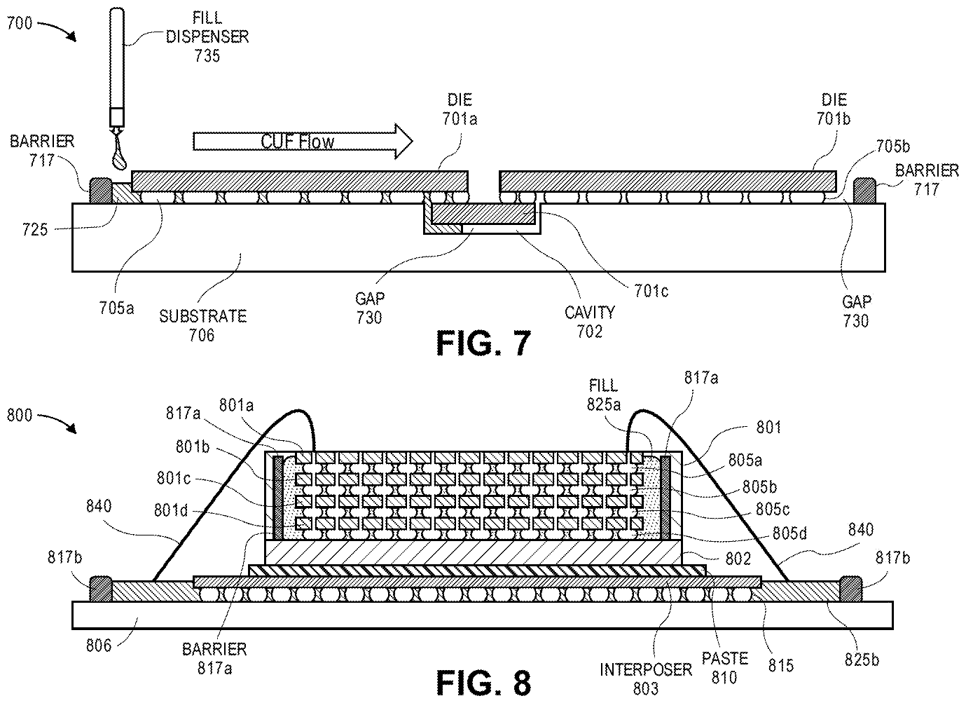

FIG. 7 is an illustration of a cross-sectional view of a device 700, in accordance with embodiments of the present disclosure. In embodiments, device 700 may include a substrate 706 that may comprise, e.g., an intervening structure such as an interposer or other structure such as, for example, a printed circuit board (PCB) that may include substrate 706 to which micro-electronic components may be coupled. In embodiments, device 700 may include both a first die 701a and a second die 701b on a surface of substrate 706. In embodiments, a third die may be an interconnect die 701c that may be located in a trench or cavity 702 of substrate 706 to couple first die 701a to second die 701b. In embodiments, first die 701a and second die 701b may include respective pluralities of interconnect structures 705a and 705b. In embodiments, a barrier structure or barrier 717 located on a surface of substrate 706 and along an outside perimeter of first die 701a and second die 701b, may confine fill material 725 to an area bordered by barrier 717. In embodiments, a height of barrier 717 may exceed a height of fill material 725 in at least a portion of an open region of substrate 706.

In embodiments, an underfill dispenser 735 may dispense underfill or fill material 725 to substantially fill a gap between first die 701a, second die 701b, and a surface of substrate 706. In embodiments, fill material 725 may substantially fill a gap 730 between interconnect die 701c and a top or other surface of substrate 706. In embodiments, interconnect die 701c may be a bridge die and device 700 may include one or more embedded multi-die interconnect bridges (EMIB)®.

FIG. 8 is an illustration of a cross-sectional view of a device 800, in accordance with embodiments of the present disclosure. In embodiments, methods of the present disclosure may include formation of device 800 that may include a memory device 801. In embodiments, memory device 801 may include interconnect wires 840 and a plurality of stacked memory die 801a, 801b, 801c, and 801d, each including a respective plurality of interconnect structures 805a, 805b, 805c, and 805d. In embodiments, interconnect structures 805a, 805b, 805c, and 805d may include solder balls, pads, or other MLI interconnect structures that may benefit from encapsulation by fill material. In embodiments, memory die 801a, 801b, 801c, and 801d may include, e.g., DRAM memory die. In embodiments, a barrier 817a may be included on a memory substrate 802 to substantially confine a fill material 825a to an area surrounded by or proximate to an inside surface of barrier 817a on memory substrate 802. In embodiments, fill material 825a may substantially surround interconnect structures 805a, 805b, 805c, and 805d and fill or substantially fill a gap or plurality of gaps between one or more of stacked memory die 801a, 801b, 801c, 801d, and/or memory substrate 802.

In embodiments, an adhesive material or a paste 810 may be located between memory substrate 802 and a micro-electronic component such as, e.g., an interposer 803. In embodiments, interposer 803 may be sandwiched between memory substrate 802 and a substrate 806. According to various embodiments, substrate 806 may include, but is not limited to, e.g., another interposer, PCB, or motherboard. In embodiments, a second barrier 817b may be located to confine or substantially confine a fill material 825a to an area surrounded by or proximate to an inside surface of barrier 817b on substrate 806. In embodiments, fill material 825b may substantially surround interconnect structures 815 of interposer 803 and fill a gap or substantially fill a gap located between interposer 803 and substrate 806.

Note that various embodiments may include various permutations including packaged DRAM devices, and/or the like. For example, in embodiments, the die (e.g., die 101 of FIGS. 1A-1C) may include a packaged memory die and the micro-electronic component (e.g., the second component of FIGS. 1A-1C, depicted as example patch 103) may include a second packaged memory die or a CPU package and the substrate (e.g., substrate 106 of FIGS. 1A-1C) may include a printed circuit board (PCB).

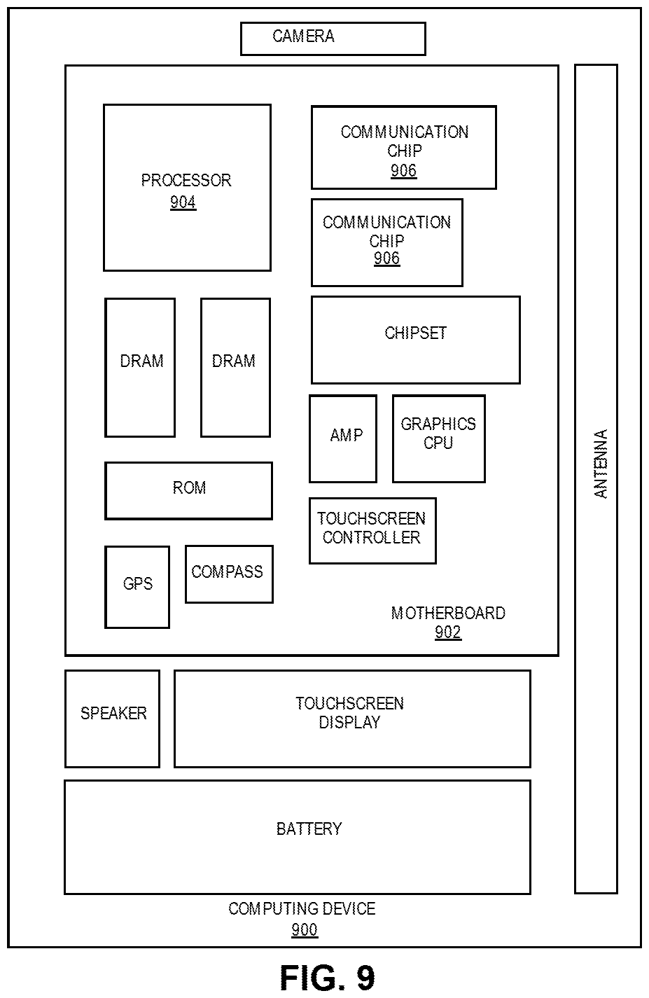

FIG. 9 illustrates a computing device 900 in accordance with various embodiments of the present disclosure. In embodiments, computing device 900 can embody a semiconductor package with a barrier to facilitate dispense of underfill or fill material to substantially confine the fill material to an area bordered by the barrier, according to any of the several disclosed embodiments and their equivalents as set forth in this disclosure. Accordingly, in FIG. 9, the computing device 900 houses a board 902. The board 902 may include a number of components, including but not limited to a processor 904 and at least one communication chip 906. The processor 904 is physically and electrically coupled to the board 902. In some implementations, the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 906 also includes an integrated circuit die, e.g., die described in connection with the above embodiments, packaged within the communication chip 906. In accordance with another implementation of the invention, the integrated circuit die of the communication chip includes one or more devices, such as MOS-FET transistors built in accordance with implementations of the invention.

In further implementations, another component housed within the computing device 900 may contain an integrated circuit die that includes one or more devices, such as MOS-FET transistors built in accordance with implementations of the invention.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

FIG. 10 illustrates an interposer 1000 that includes one or more embodiments of the invention as discussed in connection with FIGS. 1-8. The interposer 1000 is an intervening substrate used to bridge a first substrate 1002 to a second substrate 1004. The first substrate 1002 may be, for instance, an integrated circuit die, such as, e.g., discussed and shown with respect to FIGS. 1-8. The second substrate 1004 may be, for instance, a memory module, a computer motherboard, or another integrated circuit die. Generally, the purpose of an interposer 1000 is to spread a connection to a wider pitch or to reroute a connection to a different connection. For example, an interposer 1000 may couple an integrated circuit die to a ball grid array (BGA) 1006 that can subsequently be coupled to the second substrate 1004. In some embodiments, the first and second substrates 1002/1004 are attached to opposing sides of the interposer 1000. In other embodiments, the first and second substrates 1002/1004 are attached to the same side of the interposer 1000. And in further embodiments, three or more substrates are interconnected by way of the interposer 1000.

The interposer 1000 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 1008 and vias 1010, including but not limited to through-silicon vias (TSVs) 1012. The interposer 1000 may further include embedded devices 1014, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1000. In accordance with embodiments of the invention, apparatuses or processes disclosed herein may be used in the fabrication of interposer 1000.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

Example embodiment 1 may be an apparatus, comprising a micro-electronic component having a first face and a second face, wherein the second face includes interconnect structures and is opposite the first face; a fill material that fills a gap between the micro-electronic component and a substrate and substantially surrounds the interconnect structures; and a barrier structure located on a surface of the substrate and along a perimeter of the micro-electronic component, wherein a height of the barrier structure exceeds a height of the fill material in at least a portion of an open region of the substrate to confine the fill material to an area bordered by the barrier structure.

Example 2 may be the apparatus of Example 1, wherein the barrier structure is formed from a different material than from that of the substrate and the barrier structure is located along an outside perimeter of the micro-electronic component.

Example 3 may be the apparatus of Example 1, wherein the barrier structure comprises an epoxy material including one or more of amines, anhydrides, urethanes, cyanos, cationic epoxies, and/or an acrylate material.

Example 4 may be the apparatus of Example 1, wherein the fill material comprises a capillary underfill material (CUF) and forms a fillet between a side surface of the micro-electronic component and the barrier structure.

Example 5 may be the apparatus of Example 1, wherein the barrier structure is located outside a perimeter of the micro-electronic component that is substantially along a perimeter of a keep out zone (KOZ) on the surface of the substrate.

Example 6 may be the apparatus of Example 1, wherein the first face of the micro-electronic component is a top face of the micro-electronic component and remains above a level of the fill material.

Example 7 may be the apparatus of Example 1, wherein the micro-electronic component comprises a patch structure and the substrate comprises an interposer.

Example 8 may be the apparatus of Example 7, further comprising an integrated circuit die coupled to the first face of the patch structure

Example 9 may be the apparatus of any one of Examples 1-8, wherein the open region of the substrate includes an open region between the barrier structure and an edge of the micro-electronic component.

Example 10 may be a method comprising providing a micro-electronic component; coupling a face of the micro-electronic component to a surface of a substrate; dispensing a barrier structure on the surface of the substrate along an outside perimeter of an edge of the micro-electronic component; and dispensing an encapsulant material between the barrier structure and the edge of the micro-electronic component to substantially fill a gap between the face of the micro-electronic component and the substrate to substantially surround interconnect structures between the micro-electronic component and the substrate, wherein the barrier structure is to exceed a height of the encapsulant material in at least a portion of an open region of the surface of the substrate to confine the encapsulant material to an area substantially surrounded by the barrier structure.

Example 11 may be the method of Example 10, wherein dispensing the barrier structure includes dispensing the barrier structure along a substantially level surface of the surface of the substrate.

Example 12 may be the method of Example 11, wherein dispensing the barrier structure comprises dispensing an epoxy material that includes a silica filler.

Example 13 may be the method of Example 12, wherein dispensing the epoxy material comprises dispensing a first epoxy bead along the perimeter and further comprising dispensing a second epoxy bead substantially over a surface of the first epoxy bead to increase a height of the barrier structure.

Example 14 may be any one of the methods of Examples 10-13, further comprising curing the barrier structure prior to dispensing the encapsulant material.

Example 15 may be any one of the methods of Examples 10-14, wherein the open region of the surface of the substrate includes an open region between the barrier structure and the edge of the micro-electronic component

Example 16 may be a system, comprising: an integrated circuit (IC) die; a micro-electronic component coupled to the IC die and having a first face and a second face, wherein the first face is coupled to the IC die and is opposite the second face, wherein the second face includes interconnect structures; a substrate having electrical contacts formed on a surface of the substrate, wherein the substrate is coupled to the micro-electronic component via the interconnect structures of the micro-electronic component; a fill material that fills a gap between the micro-electronic component and the substrate and substantially surrounds the interconnect structures; and a barrier structure located on the surface of the substrate and along a perimeter of the micro-electronic component or the IC die, wherein an inside surface of the barrier structure is to confine the fill material to an area substantially proximate to the barrier structure, and wherein a height of the barrier structure exceeds a height of the fill material in at least a portion of an open region of the substrate.

Example 17 may be the system of Example 16, wherein the integrated circuit (IC) die is a first DRAM memory die and the micro-electronic component includes a second DRAM memory die.

Example 18 may be the system of Example 16, wherein the integrated circuit (IC) die is a first IC die located on the surface of the substrate and the micro-electronic component is an interconnect IC die embedded in the substrate to couple the first IC die to a second IC die located on the surface of the substrate.

Example 19 may be the system of Example 18, wherein the substrate includes an interposer or a motherboard and wherein the fill material comprises a capillary underfill material (CUF) to substantially fill a gap between the interconnect (integrated circuit) IC die and a surface of the substrate.

Example 20 may be the system of Example 16, wherein the micro-electronic component is a patch device and the substrate is an interposer.

Example 21 may be the system of Example 16, wherein the integrated circuit (IC) die includes a packaged memory die and the micro-electronic component includes a second packaged memory die or a CPU package and the substrate includes a printed circuit board (PCB).

Example 22 may be the system of Examples 20 or 21, wherein the fill material comprises a capillary underfill material (CUF) and forms a fillet between a side surface of the micro-electronic component and the barrier structure.

Example 23 may be the system of any one of Examples 16-22, wherein the barrier structure is formed from a different material than the substrate and the barrier structure is located along an outside perimeter of the micro-electronic component.

Example 24 may be the system of any one of Examples 16-23, wherein the barrier structure comprises an epoxy material including one or more of amines, anhydrides, urethanes, cyanos, cationic epoxies, and/or an acrylate material.

Example 25 may be the system of any one of Examples 16-24, wherein the barrier structure is located outside a perimeter of the micro-electronic component that is substantially along a perimeter of a keep out zone (KOZ) on the surface of the substrate.

Various embodiments may include any suitable combination of the above-described embodiments including alternative (or) embodiments of embodiments that are described in conjunctive form (and) above (e.g., the “and” may be “and/or”). Furthermore, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to specific implementations disclosed in the specification and the claims. Rather, the scope is to be determined entirely by the following claims, which are to be construed in accordance with established doctrines of claim interpretation.

What is claimed is:

1. An apparatus, comprising:
a micro-electronic component having a first face and a second face, wherein the second face includes interconnect structures and is opposite the first face;
a fill material that fills a gap between the micro-electronic component and a substrate and substantially surrounds the interconnect structures; and
a barrier structure located on a surface of the substrate and along a perimeter of the micro-electronic component, wherein a height of the barrier structure exceeds a height of the fill material in at least a portion of an open region of the substrate to confine the fill material to an area bordered by the barrier structure.

2. The apparatus of claim 1, wherein the barrier structure is formed from a different material than from that of the substrate and the barrier structure is located along an outside perimeter of the micro-electronic component.

3. The apparatus of claim 1, wherein the barrier structure comprises an epoxy material including one or more of amines, anhydrides, urethanes, cyanos, cationic epoxies, and/or an acrylate material.

4. The apparatus of claim 1, wherein the fill material comprises a capillary underfill material (CUF) and forms a fillet between a side surface of the micro-electronic component and the barrier structure.

5. The apparatus of claim 1, wherein the barrier structure is located outside a perimeter of the micro-electronic component that is substantially along a perimeter of a keep out zone (KOZ) on the surface of the substrate.

6. The apparatus of claim 1, wherein the first face of the micro-electronic component is a top face of the micro-electronic component and remains above a level of the fill material.

7. The apparatus of claim 1, wherein the micro-electronic component comprises a patch structure and the substrate comprises an interposer.

8. The apparatus of claim 7, further comprising an integrated circuit die coupled to the first face of the patch structure

9. The apparatus of claim 1, wherein the open region of the substrate includes an open region between the barrier structure and an edge of the micro-electronic component.

10. A method comprising:
providing a micro-electronic component;
coupling a face of the micro-electronic component to a surface of a substrate;
dispensing a barrier structure on the surface of the substrate along an outside perimeter of an edge of the micro-electronic component; and
dispensing an encapsulant material between the barrier structure and the edge of the micro-electronic component to substantially fill a gap between the face of the micro-electronic component and the substrate to substantially surround interconnect structures between the micro-electronic component and the substrate, wherein the barrier structure is to exceed a height of the encapsulant material in at least a portion of an open region of the surface of the substrate to confine the encapsulant material to an area substantially surrounded by the barrier structure.

11. The method of claim 10, wherein dispensing the barrier structure includes dispensing the barrier structure along a substantially level surface of the surface of the substrate.

12. The method of claim 11, wherein dispensing the barrier structure comprises dispensing an epoxy material that includes a silica filler.

13. The method of claim 12, wherein dispensing the epoxy material comprises dispensing a first epoxy bead along the perimeter and further comprising dispensing a second epoxy bead substantially over a surface of the first epoxy bead to increase a height of the barrier structure.

14. The method of claim 10, further comprising curing the barrier structure prior to dispensing the encapsulant material.

15. The method of claim 10, wherein the open region of the surface of the substrate includes an open region between the barrier structure and the edge of the micro-electronic component

16. A system, comprising:
an integrated circuit (IC) die;
a micro-electronic component coupled to the IC die and having a first face and a second face, wherein the first face is coupled to the IC die and is opposite the second face, wherein the second face includes interconnect structures;
a substrate having electrical contacts formed on a surface of the substrate, wherein the substrate is coupled to the micro-electronic component via the interconnect structures of the micro-electronic component;
a fill material that fills a gap between the micro-electronic component and the substrate and substantially surrounds the interconnect structures; and
a barrier structure located on the surface of the substrate and along a perimeter of the micro-electronic component or the IC die, wherein an inside surface of the barrier structure is to confine the fill material to an area substantially proximate to the barrier structure, and wherein a height of the barrier structure exceeds a height of the fill material in at least a portion of an open region of the substrate.

17. The system of claim 16, wherein the barrier structure is formed from a different material than the substrate and the barrier structure is located along an outside perimeter of the micro-electronic component.

18. The system of claim 16, wherein the integrated circuit (IC) die is a first DRAM memory die and the micro-electronic component includes a second DRAM memory die.

19. The system of claim 16, wherein the integrated circuit (IC) die is a first IC die located on the surface of the substrate and the micro-electronic component is an interconnect IC die embedded in the substrate to couple the first IC die to a second IC die located on the surface of the substrate.

20. The system of claim 19, wherein the substrate includes an interposer or a motherboard and wherein the fill material comprises a capillary underfill material (CUF) to substantially fill a gap between the interconnect (integrated circuit) IC die and a surface of the substrate.

21. The system of claim 16, wherein the micro-electronic component is a patch device and the substrate is an interposer.

22. The system of claim 16, wherein the integrated circuit (IC) die includes a packaged memory die and the micro-electronic component includes a second packaged memory die or a CPU package and the substrate includes a printed circuit board (PCB).
